(19) United States
(12) Patent Application Publication
(10) Pub. No.: US 2011/0215386 A1
(43) Pub. Date: Sep. 8, 2011

(54) SEMICONDUCTOR DEVICE AND METHOD OF MANUFACTURING THE SEMICONDUCTOR DEVICE

(75) Inventor: Tatsuya SUZUKI, Kanagawa (JP)

(73) Assignee: Renesas Electronics Corporation

(21) Appl. No.: 13/039,047

(22) Filed: Mar. 2, 2011

(30) Foreign Application Priority Data
Mar. 4, 2010 (JP) 2010-048206

(51) Int. Cl. H01L 29/772; H01L 21/283

(52) U.S. Cl. 257/288; 438/595; 257/E21.159; 257/E29.242

(57) ABSTRACT

Unintended full siliciding of a polysilicon gate electrode is prevented.

The invention provides a method of manufacturing a semiconductor device, the method including: forming a stack structure by stacking a gate insulating film and a silicon layer in this order on a substrate; forming an offset spacer along the side surfaces of the stack structure, the offset spacer including a SiN film; cleaning an exposed region of an upper surface of the silicon layer with a chemical solution after the forming the offset spacer; forming a metal film after the cleaning, the metal film covering at least the exposed region; and performing siliciding through a heating process after the forming the metal film. The SiN film of the offset spacer is a SiN film formed by ALD at 450° C. equal to or higher, or a SiN film having a tensile/compressive stress of 1 Gpa or higher. The chemical solution is DHF having a ratio by weight of 1/100 or higher in HF/H₂O or buffered hydrofluoric acid.

This application is based on Japanese patent application No. 2010-048206, the content of which is incorporated hereinto by reference.

### BACKGROUND

1. Technical Field

The present invention relates to a semiconductor device and a method of manufacturing the semiconductor device.

2. Related Art

There have been semiconductor devices having a silicided silicon gate electrode. A silicide is normally formed by forming a metal layer (a Ni layer, for example) on a silicon surface and causing the metal to react with the silicon through a heating process.

As a technique relevant to the present invention, Japanese Laid-Open Patent Publication No. 2008-171910 discloses a method of manufacturing a semiconductor device having HfSiON films formed as offset spacers.

In a smaller silicon gate electrode, the silicon more easily reacts with the metal formed in the surface, and the entire silicon is more likely to turn into silicide (full siliciding).

Since silicide is a midgap metal, if even partial full siliciding occurs in the salicide gate, the threshold voltage of the transistor varies (inmost cases, the absolute value becomes larger), and desired transistor characteristics cannot be achieved. Also, in a MIPS (Metal Inserted Poly-Si Stack) structure formed by a high-k film/a word function control metal thin film/a silicon gate, partial full siliciding changes the threshold voltage of the transistor from a desired value. Further, in a case where a Ni silicide layer is used as an e-fuse, the cutoff voltage of the e-fuse becomes higher due to partial full siliciding, and a larger amount of current is required, resulting in a variation.

### SUMMARY

The inventor discovered that full siliciding of a silicon gate electrode also easily occurs due to the following factors. Those factors are described below, with reference to the operation flow of siliciding of a silicon gate electrode suggested by the inventor.

First, as shown in FIG. 7A, a stack structure formed by a gate insulating film 102, a metal gate electrode 101, and a polysilicon gate electrode 100 is formed on a silicon substrate 107, and offset spacers (SiN) 103 and sidewall spacers 104 are formed along the side surfaces of the stack structure. Also, extension implantation regions 105 and source/drain regions 106 are formed in the silicon substrate 107.

After that, a WET process is performed as the preprocessing for siliciding (immediately before Ni sputtering). That is, the surfaces of the substrate 107 in which the source/drain regions 106 are formed, and the exposed face (the upper face) of the polysilicon gate electrode 100 are cleaned with the use of a chemical solution, to remove oxide films. The oxide films are formed by an ashing process or the like performed after gate electrode processing, for example.

Here, the above described WET process is performed with the use of DHF (HF:H₂O=about 1:300), for example. However, through the WET process, the offset spacers (SiN) 103 and the sidewall spacers 104 formed along the side surfaces of the polysilicon gate electrode 100 are partially removed. FIG. 7B shows the structure immediately after the WET process. After the offset spacers (SiN) 103 and the sidewall spacers 104 are partially removed as described above, and those spacers (103 and 104) become smaller in height, the side surfaces of the polysilicon gate electrode 100 are exposed.

In this situation (see FIG. 7B), a metal film (a Ni film, for example) that covers the surfaces of the substrate 107 in which the source/drain regions 106 are formed and the exposed face (the upper face) of the polysilicon gate electrode 100 is formed by a sputtering technique for siliciding. As a result, the metal film is also in contact with the exposed side surfaces of the polysilicon gate electrode 100, as shown in FIG. 7C. If heating and siliciding are performed by a RTA (Rapid Thermal Annealing) technique or the like in such a situation, the reaction between the metal and the silicon progresses not only through the upper face but also through the side faces of the polysilicon gate electrode 100, as shown in FIG. 7D. That is, the metal flows into the polysilicon gate electrode 100 through the side surfaces of the polysilicon gate electrode 100, and excess metal diffuses deep into the polysilicon gate electrode 100 that has a relatively small gate length. In some cases, full siliciding occurs. The full siliciding does not occur in a controlled manner, but occurs irregularly in the wafer plane. That is, the gate silicide film thickness varies. As a result, the threshold voltage of the transistor differs from a desired value (a set value), or the variations in cutoff voltages and resistances in cutting e-fuses become wider, for example.

Then, the inventor completed the following inventions. In one embodiment, there is provided a method of manufacturing a semiconductor device, including forming a stack structure by stacking a gate insulating film and a silicon layer in this order on a substrate, forming an offset spacer along side surfaces of the stack structure, the offset spacer including a SiN film, cleaning an exposed region of an upper surface of the silicon layer with a chemical solution after the forming the offset spacer, forming a metal film after the cleaning, the metal film covering at least the exposed region, and performing siliciding through a heating process after the forming the metal film, wherein the SiN film formed in the forming the offset spacer is a SiN film formed by ALD at 450° C. or higher, or a SiN film having a tensile/compressive stress of 1 Gpa or higher, and wherein the chemical solution used in the cleaning is DHF having a ratio by weight of 1/100 or higher in HF/H₂O, or buffered hydrofluoric acid.

According to one aspect of the present invention, the structure of the offset spacer and the type of chemical solution to be used in the cleaning process are appropriately selected. Accordingly, in the oxide film removing process to be performed as the preprocessing for the siliciding, the amount of offset spacers to be removed from the side surfaces of the silicon layer can be restricted. That is, exposure of the side surfaces of the silicon layer after the cleaning process can be restrained. As a result, the metal film later formed on the silicon layer for siliciding can be restrained from coming into contact with the side surfaces of the silicon layer.

Accordingly, the metal can be prevented from flowing into the silicon layer through the side surfaces of the silicon layer when siliciding is performed after the metal film is formed. Thus, the metal flows into the silicon layer mainly through the upper surface of the silicon layer.

In such a case, the amount of metal flowing into the silicon layer per unit time can be restricted. Accordingly, full siliciding can be effectively avoided. The film thickness of the silicide after the siliciding process depends mainly on the film thickness of the metal film formed on the upper surface of the silicon layer. That is, the film thickness of the metal film and the variation of the film thickness are controlled, so that the film thickness of the silicide and the variation of the film thickness can be controlled.

According to the present invention, unintended full siliciding of a polysilicon gate electrode can be prevented.

According to another aspect of the present invention, the semiconductor device comprises a semiconductor substrate, a stack structure, an offset spacer, and a sidewall spacer. The stack structure comprises a gate insulating film provided on the semiconductor substrate, and a silicon layer provided on the gate insulating film. The offset spacer is provided on side surfaces of the stack structure. The sidewall spacer is provided along the side surfaces of the stack structure to cover the offset spacer. The height of a top surface of the offset spacer is higher than that of a top surface of the sidewall spacer.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A through 1E are cross-sectional views schematically showing the procedures according to an example of method of manufacturing a semiconductor device of a first embodiment;

FIGS. 2A through 2D are cross-sectional views schematically showing the procedures according to an example of method of manufacturing a semiconductor device of a second embodiment;

FIG. 3 is a table showing the wet etching rate selectivity of each type of film;

FIG. 4 is a graph for explaining the effects of the present invention;

FIG. 5 is a graph for explaining the effects of the present invention;

FIG. 6 is a graph for explaining the effects of the present invention; and

FIGS. 7A through 7E are cross-sectional views schematically showing the procedures according to a reference example of manufacturing a semiconductor device.

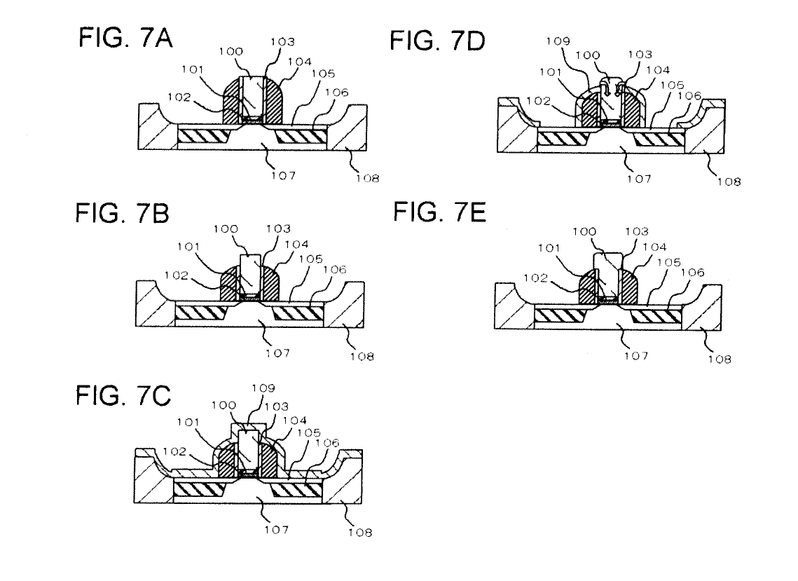

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

The following is a description of embodiments of the present invention, with reference to the accompanying drawings. In all the drawings, like components are denoted by like reference numerals, and explanation of them will not be repeated.

### First Embodiment

The method of manufacturing a semiconductor device of this embodiment includes a stack structure forming process, an offset spacer forming process, a cleaning process, a metal film forming process, and a siliciding process.

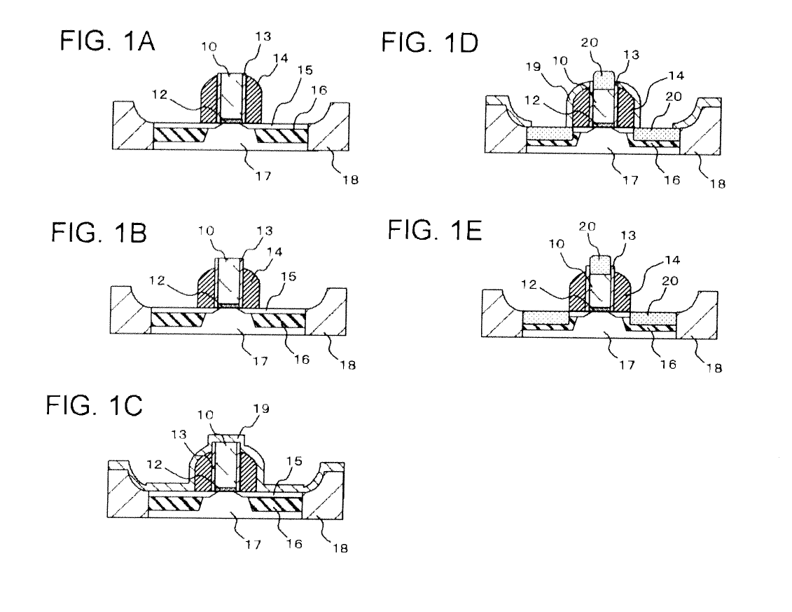

In the stack structure forming process, as shown in FIG. 1A, a stack structure (10, 12) formed by stacking a gate insulating film 12 and a silicon layer 10 in this order is placed on a substrate 17.

For example, after element isolation regions 18 are formed in the substrate 17 by a STI (Shallow Trench Isolation) technique or a LOCOS (Local Oxidation Of Silicon) technique, ions are implanted into the region enclosed by the element isolation regions 18 as needed, so as to form a well. An oxide film to be the gate insulating film 12 is then formed on the surface of the substrate 17 by a thermal oxidation technique or the like. After that, a polysilicon layer is formed on the oxide film by a CVD (Chemical Vapor Deposition) technique, for example, and the insulating film and the polysilicon layer are partially removed by a photolithography technique and an etching technique, to form the stack structure (10, 12) shown in FIG. 1A.

The substrate 17 is not particularly limited to a certain material, and may be a Si substrate, a SiGe substrate, a Ge substrate, a SOI (Silicon On Insulator) substrate, or the like. The gate insulating film 12 may be a high-k insulating film. The silicon layer 10 may be a polysilicon layer or an amorphous silicon layer.

The stack structure forming process of this embodiment may be a process to form a stack structure by stacking the gate insulating film 12, a work function control layer (not shown), and the silicon layer 10 in this order. The work function control layer may contain TaSiN, TaSi, or TaSi₂ in the case of an n-type semiconductor device, and may contain Ru, Pt, or Ir in the case of a p-type semiconductor device, for example. The method of forming such a stack structure can be realized according to the method of forming the above described stack structure (10, 12).

The offset spacer forming process is carried out after the stack structure forming process, and, as shown in FIG. 1A, offset spacers 13 are formed along the side surfaces of the stack structure (10, 12). The offset spacers 13 each includes a SiN film. For example, the offset spacers 13 may be formed by SiN films. Alternatively, each of the offset spacers 13 may be a stack structure formed by a SiN film in contact with the stack structure (10, 12) and at least one film that covers the SiN film and is of a different kind from the SiN film.

The SiN film of each of the offset spacers 13 is a SiN film formed at 450° C. or higher by an ALD (Atomic Layer Deposition) technique, or a SiN film having a tensile/compressive stress of 1 Gpa or higher. The SiN film having a tensile/compressive stress of 1 Gpa or higher can be formed by a plasma CVD technique involving a vacuum of 100 mTorr or lower and a substrate temperature of 450° C. The raw material gas may be a trimethylsilane gas, for example.

In the offset spacer forming process, the above described SiN film is formed on the substrate 17, so as to cover the stack structure (10, 12), for example. Anisotropic etching is then performed so as to leave SiN films along the side surfaces of the stack structure (10, 12), and remove the upper surface of the stack structure (10, 12) and the SiN films on the substrate 17. In this manner, as shown in FIG. 1A, the offset spacers 13 are formed. Here the offset spacers 13 are formed so that at least one part of the upper surface of the silicon layer 10 is exposed. Also the offset spacers 13 cover all of the side surface of the stack structure (10, 12). Top surfaces of the offset spacers 13 have the same height as a top surface of the silicon layer 10.

After that, extension implantation regions 15, sidewall spacers 14, and source/drain regions 16 are formed. For example, predetermined ions are implanted into the substrate 17, with the stack structure (10, 12) and the offset spacers 13 serving as masks. In this manner, the extension implantation regions 15 are formed. An insulating film is then formed, and etching is performed on the insulating film, to form the sidewall spacers 14. The sidewall spacers 14 may be formed by silicon oxide films. After that, with the stack structure (10, 12), the offset spacers 13, and the sidewall spacers 14 serving as masks, predetermined ions are implanted into the substrate 17, to form the source/drain regions 16. In this embodiment, the method and materials for forming the extension implantation regions 15, the sidewall spacers 14, and the source/drain regions 16 are not particularly limited.

Through the above procedures, the structure shown in FIG. 1A can be obtained.

The cleaning process is carried out after the offset spacer forming process is performed or after the structure shown in FIG. 1A is obtained. In the cleaning process, an exposed region of the upper surface of the silicon layer 10 with a chemical solution. By the same process by this process, the surfaces of the substrate 17 in which the source/drain regions 16 are formed may also be cleaned. The cleaning in the cleaning process is performed to remove oxide films formed on the surfaces to be cleaned. The oxide films are formed by an asking processor the like performed after the photolithography and etching procedures are carried out in the stack structure forming process, for example.

The chemical solution used in the cleaning process of this embodiment is DHF (Diluted HF) having a ratio by weight HF/H₂O of 1/100 or higher, or buffered hydrofluorescent acid (BHF). Hereinafter, the DHF of 1/100 in HF/H₂O will be expressed as DHF (1/100), and DHFs having other densities will be expressed in the same manner as above.

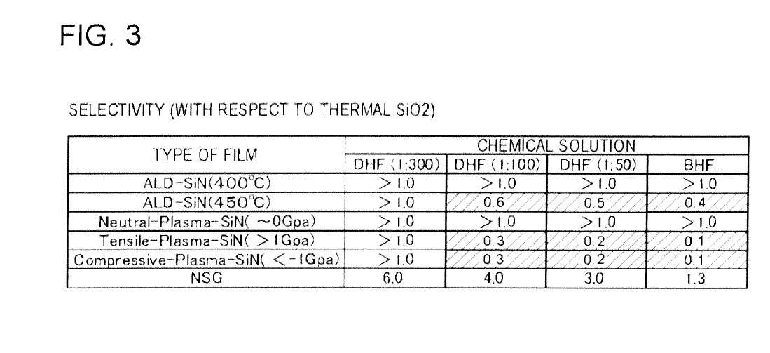

FIG. 3 shows the wet etching rate selectivities of films of different kinds with respect to a thermal SiO₂ film. The films of different kinds are made of different materials, and are manufactured by different methods. The thermal SiO₂ film is a SiO₂ film formed through thermal oxidation. Where the value of the wet etching rate selectivity is 1, the etching rate is the same as that of the thermal SiO₂ film. Where the value of the wet etching rate selectivity is smaller than 1, the etching rate is lower than that of the thermal SiO₂ film. In the table, each “ALD-SiN (temperature)” indicates a SiN film formed by ALD at the temperature shown in the brackets. Each “(stress state)-Plasma-SiN (stress value)” indicates a SiN film that is formed by plasma CVD and has the stress value shown in the brackets. After wet etching was performed on the surface on which a resist patterned on a measured film formed on the wafer was formed, the etching rates were measured by removing the resist and measuring the depth of follows formed by the etching.

As shown in FIG. 3, by performing etching with the use of the chemical solutions (DHF (1/100), DHF (1/50), and BHF) of this embodiment, the selectivities of the SiN films (ALD-SiN (450° C.), Tensile-Plasma-SiN (>1 Gpa), and Compressive-Plasma-SiN (<−1 Gpa)) of the offset spacers 13 of this embodiment with respect to thermal SiO₂ to be removed can be made lower than those of films of other kinds. That is, when the oxide film is removed in the cleaning process, removal of the offset spacers 13 can be restrained. As a result, as shown in FIG. 1B, exposure of the side surfaces of the silicon layer 10 after the cleaning process can be restrained. A part of side surfaces of the offset spacers 13 are exposed due to etching the sidewall spacers 14. In other words, the height of a top surface of the offset spacers 13 is higher than that of a top surface of the sidewall spacers 14.

The metal film forming process is performed after the cleaning process. In the metal film forming process, a metal film 19 is formed to cover at least the exposed region of the upper surface of the silicon layer 10, as shown in FIG. 1C. For example, the metal film 19 of approximately 10 nm in thickness may be formed by a sputtering technique.

The metal film 19 may also be formed to cover the surfaces of the substrate 17 in which the source/drain regions 16 are formed, as shown in FIG. 1C. The type of the metal film 19 is not particularly limited, and the metal film 19 may be a film containing at least one of the following elements: Ni, Ti, Co, Ta, W, and Pt.

In this embodiment, exposure of the side surfaces of the silicon layer 10 due to the cleaning process can be restrained. Accordingly, the metal film 19 formed in the metal film forming process can be restrained from coming into contact with the side surfaces of the silicon layer 10.

The siliciding process is performed after the metal film forming process. In the siliciding process, the substrate 17 in the condition illustrated in FIG. 1C is heated, and siliciding is performed. For example, heating at 350° C. is performed by RTA for about thirty seconds. As a result, metal flows from the contact portion between the silicon layer 10 and the metal film 19, and diffuses into the silicon layer 10. In this embodiment, contact of the metal film 19 with the side surfaces of the silicon layer 10 is restrained. Therefore, the metal flows and diffuses into the silicon layer 10 mainly through the upper surface of the silicon layer 10. That is, full siliciding is effectively prevented, and a structure having a silicide 20 formed from an upper portion of the silicon layer 10 can be obtained as shown in FIG. 1D.

After that, the metal film 19 remaining after the siliciding is removed, and the structure shown in FIG. 1E is obtained. In other words, the unreacted metal in the metal film 19 is removed. The unreacted metal is unreacted with the silicon layer 10 during the siliciding process. For example, in a case where a Ni film is formed as the metal film 19, a mixture of sulfuric acid and a hydrogen peroxide solution (the ratio by weight (sulfuric acid/hydrogen peroxide solution) being in the range of 2 to 4) may be used, and wet etching may be performed to obtain the structure.

Thereafter, an interlayer insulating film (not shown), contacts (not shown), and interconnects (not shown) are formed by using known techniques.

By the method of manufacturing a semiconductor device according to this embodiment, the amount of offset spacers 13 to be removed from the side surfaces of the silicon layer 10 can be restricted in the oxide film removing process to be performed as the preprocessing for the siliciding process. That is, exposure of the side surfaces of the silicon layer 10 due to the preprocessing (the oxide film removing process) for the siliciding process can be restrained. As a result, the metal film formed for siliciding can be restrained from coming into contact with the side surfaces of the silicon layer 10.

Metal can be prevented from flowing into the silicon layer 10 through the side surfaces of the silicon layer 10 when siliciding is performed in a later stage. Accordingly, metal flows into the silicon layer 10 mainly through the upper surface of the silicon layer 10.

In this manner, contact of the metal with the silicon layer 10 is reduced, so that the amount of metal flowing into the silicon layer 10 per unit time can be restricted. Accordingly, by the method of manufacturing a semiconductor device according to this embodiment, full siliciding can be effectively avoided. The film thickness of the silicide 20 after the siliciding process (or the thickness of the silicide 20 in a direction perpendicular to the substrate 17) depends mainly on the film thickness of the metal film 19 formed on the upper surface of the silicon layer 10. That is, the film thickness of the metal film 19 and the variation of the film thickness are controlled, so that the film thickness of the silicide 20 and the variation of the film thickness can be controlled.

### Second Embodiment

A method of manufacturing a semiconductor device according to this embodiment differs from that of the first embodiment in that: 1) the process to form the sidewall spacers 14 that are formed by NSG (Non-doped Silicate Glass) films and cover the offset spacers 13 formed along the side surfaces of the stack structure (10, 12) is performed after the offset spacer forming process but prior to the cleaning process; and 2) BHF is used as the chemical solution in the cleaning process.

To form the sidewall spacers 14 of this embodiment, a NSG film to cover the stack structure (10, 12) and the offset spacers 13 may be formed on the substrate 17, by CVD, for example, and anisotropy etching may be performed to partially remove the NSG film.

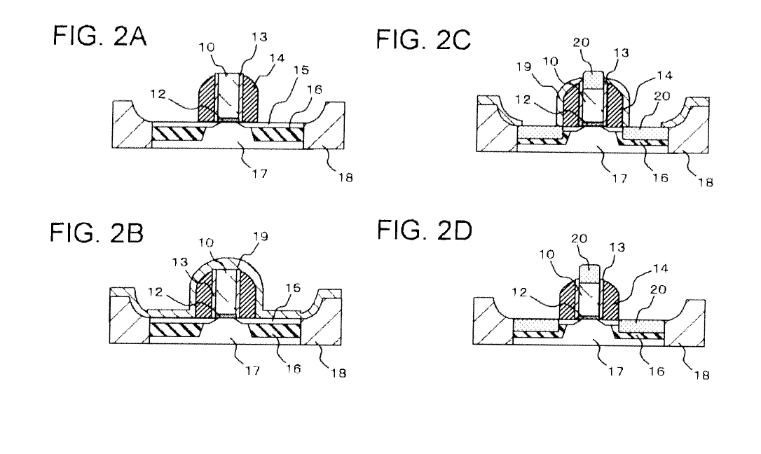

FIG. 3 shows the wet etching rate selectivities of films of different kinds with respect to a thermal SiO₂ film. The films of different kinds are made of different materials, and are manufactured by different methods. As can be seen from the wet etching rate selectivities of the NSG film shown in this table, the selectivity with respect to thermal SiO₂ in a case where BHF is selected as the chemical solution is much lower than that of any of the other chemical solutions. That is, when the oxide film is removed in the cleaning process, removal of the sidewall spacers 14 can be restrained. As a result, as shown in FIG. 2A, the side surfaces of the silicon layer 10 can be thickly covered with the offset spacers 13 and the sidewall spacers 14 after the cleaning process.

After that, as shown in FIGS. 2B through 2D, the same processes as those of the first embodiment are performed.

By the method of manufacturing a semiconductor device according to this embodiment, the amount of sidewall spacers 14 to be removed in the cleaning process can be reduced. Accordingly, contact of the offset spacers 13 with the chemical solution in the cleaning process can be restrained. As a result, the amount of offset spacers 13 to be removed in the cleaning process can be reduced, and exposure of the side surfaces of the silicon layer 10 can be further restrained.

Since the side surfaces of the silicon layer 10 can be thickly covered with the offset spacers 13 and the sidewall spacers 14, the distance from the metal film 19 (see FIG. 2B) formed on each sidewall spacer 14 to the silicon layer 10 can be made longer.

As described above, by the method of manufacturing a semiconductor device according to this embodiment, the metal flow into the silicon layer 10 through the side surfaces in the siliciding process can be more effectively prevented than in the first embodiment. As a result, full siliciding can be effectively avoided, and the silicide thickness variation can be effectively made smaller.

### EXAMPLES

### Example 1

By using the method of manufacturing a semiconductor device according to the first embodiment, a semiconductor device was manufactured.

SiN films were formed as the offset spacers by ALD at 450° C. NSG films were formed as the sidewall spacers by CVD at 400° C. The offset spacers and the sidewall spacers were designed so that the uppermost portions of the spacers would be at the same height as the uppermost portion of the silicon layer of the stack structure. DHF (1/100) was used as the chemical solution in the cleaning process. The amount of etching in the cleaning process was set at the amount equivalent to 100% overetching or the amount equivalent to 5-nm oxide film etching, since the film thickness of the thermal SiO₂ film was about 2.5 nm. Further, a Ni film having a film thickness of 10 nm was formed as the metal film by a sputtering technique. Siliciding was performed through a 30-second heating process by RTA at 350° C.

After the cleaning process, the distance from the upper surface of the silicon layer of the stack structure to the uppermost portion of each offset spacer was measured, and the measurement result was about 3 nm. Also, the distance from the upper surface of the silicon layer of the stack structure to the uppermost portion of each sidewall spacer was about 20 nm.

The film thickness of the silicide formed in the silicon layer of the stack structure was measured by cross-sectional observation using STEM (Scanning Transmission Electron Microscope), to find that the mean film thickness was 25 nm, and the variation (the difference between the greatest film thickness and the smallest film thickness) was about 10 nm. Here, the film thickness is the thickness of the silicide in a direction perpendicular to the substrate.

### Example 2

A semiconductor device was manufactured by using the method of manufacturing a semiconductor device according to the second embodiment.

The only difference from Example 1 is that the chemical solution to be used in the cleaning process is BHF.

After the cleaning process, the distance from the upper surface of the silicon layer of the stack structure to the uppermost portion of each offset spacer was measured, and the measurement result was about 2 nm. Also, the distance from the upper surface of the silicon layer of the stack structure to the uppermost portion of each sidewall spacer was about 6.5 nm.

The film thickness of the silicide formed in the silicon layer of the stack structure was measured by cross-sectional observation using STEM, to find that the mean film thickness was 22 nm, and the variation (the difference between the greatest film thickness and the smallest film thickness) was about 3 nm.

### COMPARATIVE EXAMPLE

### Comparative Example 1

The differences from Example 1 are that SiN films were formed as the offset spacers by ALD at 400° C., and DHF (1/300) was used as the chemical solution in the cleaning process.

After the cleaning process, the distance from the upper surface of the silicon layer of the stack structure to the uppermost portion of each offset spacer was measured, and the measurement result was 10 nm or longer. Also, the distance from the upper surface of the silicon layer of the stack structure to the uppermost portion of each sidewall spacer was about 30 nm.

The film thickness of the silicide formed in the silicon layer of the stack structure was measured by cross-sectional observation using STEM, to find that the mean film thickness was 400 nm, and the variation (the difference between the greatest film thickness and the smallest film thickness) was about 20 nm.

As is apparent from the above results, by the method of manufacturing a semiconductor device according to the first embodiment, the amount of offset spacers to be removed can be restricted by the preprocessing (removal of the oxide film) performed prior to the siliciding process. Also, by the method of manufacturing a semiconductor device according to the second embodiment, the amount of offset spacers and sidewall spacers to be removed can be restricted by the preprocessing (removal of the oxide film) performed prior to the siliciding process.

Further, as is apparent from the above, by the methods of manufacturing a semiconductor device according to the first and second embodiments, the variation of the film thickness of the silicide formed in the polysilicon layer and progression of siliciding can be restricted.

When the cutoff voltages and the resistance variations of the e-fuses were compared among Examples 1, 2, and Comparative Example 1, the variations observed in Examples 1 and 2 were ten or more times better than the variation observed in Comparative Example 1.

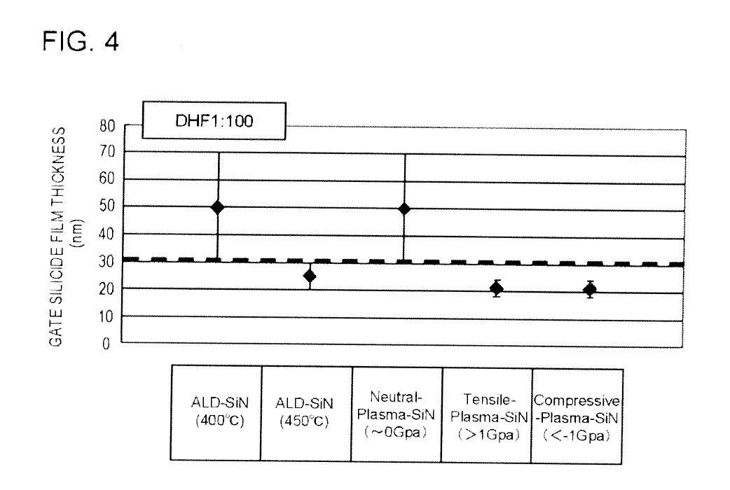

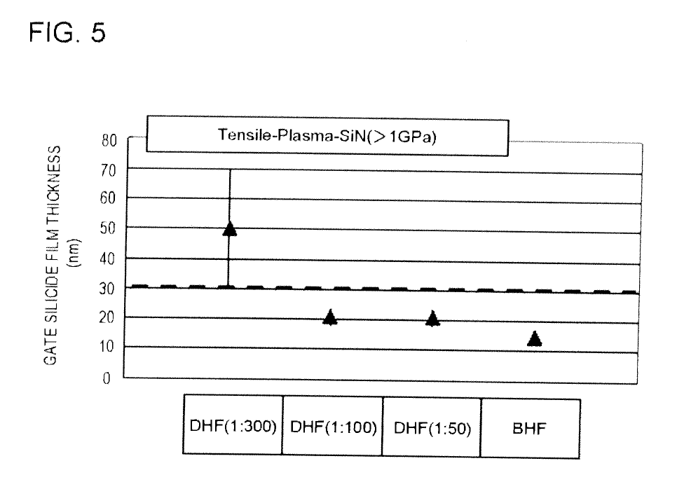

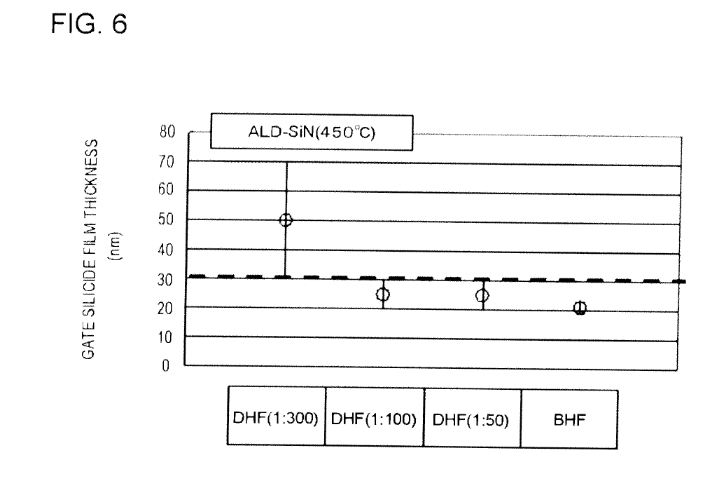

FIGS. 4 through 6 show the results of measurement carried out in the same manner as above, while the film types of offset spacers and the kinds of chemical solutions used in the cleaning process were changed.

As can be seen from the results, by each method of manufacturing a semiconductor device according to the present invention, the variation of the film thickness of the silicide formed in the polysilicon layer and progression of the siliciding can be restrained.

It is apparent that the present invention is not limited to the above embodiments, and may be modified and changed without departing from the scope and spirit of the invention.

What is claimed is:

1. A method of manufacturing a semiconductor device, comprising:
forming a stack structure by stacking a gate insulating film and a silicon layer in this order on a substrate;
forming an offset spacer along side surfaces of said stack structure, said offset spacer including a SiN film;
cleaning an exposed region of an upper surface of said silicon layer with a chemical solution after said forming the offset spacer;
forming a metal film after said cleaning, said metal film covering at least said exposed region; and
performing siliciding through a heating process after said forming the metal film,
wherein said SiN film formed in said forming the offset spacer is a SiN film formed by ALD at 450° C. or higher, or a SiN film having a tensile/compressive stress of 1 Gpa or higher, and
wherein said chemical solution used in said cleaning is DHF having a ratio by weight of 1/100 or higher in HF/H₂O, or buffered hydrofluoric acid.

2. The method of manufacturing a semiconductor device according to claim 1, further comprising:
forming a sidewall spacer along said side surface of said stack structure to cover said offset spacer, prior to said cleaning.

3. The method of manufacturing a semiconductor device according to claim 1, further comprising:
removing an unreacted metal in said metal film after said performing siliciding, and
wherein said unreacted metal is unreacted with said silicon layer in said performing siliciding.

4. The method of manufacturing a semiconductor device according to claim 1, wherein said sidewall spacer is comprised of silicon oxide.

5. The method of manufacturing a semiconductor device according to claim 2,
wherein said sidewall spacer is formed with a NSG (Non-doped Silicate Glass) film, and
wherein said chemical solution is buffered hydrofluoric acid.

6. The method of manufacturing a semiconductor device according to claim 1,
wherein, in said forming an offset spacer, said offset spacer is forming so that at least one part of the upper surface of said silicon layer is exposed.

7. The method of manufacturing a semiconductor device according to claim 1,
wherein said cleaning causes that the height of a top surface of said offset spacer is higher than that of a top surface of said sidewall spacer.

8. The method of manufacturing a semiconductor device according to claim 1, wherein said silicon layer is comprised of polycrystalline silicon.

9. A semiconductor device, comprising:
a semiconductor substrate;
a stack structure comprising a gate insulating film provided on the semiconductor substrate, and a silicon layer provided on the gate insulating film;
an offset spacer provided on side surfaces of the stack structure;
a sidewall spacer provided along the side surfaces of the stack structure to cover the offset spacer,
wherein the height of a top surface of the offset spacer is higher than that of a top surface of the sidewall spacer.

10. The semiconductor device according to claim 9,
wherein the offset spacer covers all of the side surface of the stack structure.

11. The semiconductor device according to claim 9,
wherein a top surface of the offset spacer has the same height as a top surface of the silicon layer.
